(19) United States
(12) Patent Application Publication
(10) Pub. No.: US 2022/0384545 A1
(43) Pub. Date: Dec. 1, 2022

(54) DISPLAY SUBSTRATE, DISPLAY DEVICE AND MASK

(71) Applicant: BOE Technology Group Co., Ltd., Beijing (CN)

(72) Inventors: Kuo SHEN, Beijing (CN); Jia ZHAO, Beijing (CN); Shanshan BAI, Beijing (CN); Pinfan WANG, Beijing (CN)

(21) Appl. No.: 17/765,557

(22) PCT Filed: May 21, 2021
(86) PCT No.: PCT/CN2021/095158

§ 371 Date: Mar. 31, 2022

(30) Foreign Application Priority Data
Jun. 19, 2020 (CN) 202010568148.0

(51) Int. Cl. H01L 27/32; H01L 51/00; C23C 14/04

(52) U.S. Cl. CPC H01L 27/3246; H01L 51/0097; C23C 14/042; H01L 2251/5338

(57) ABSTRACT

Embodiments of the present disclosure provide a display substrate, a display device and a mask, belonging to the field of display technology. The display substrate in the embodiments of the present disclosure has a stretchable area including an opening region, a bridge region and an island region. The display substrate includes: a base substrate; a plurality of light-emitting units, each light-emitting unit including a light-emitting device of at least one color; each island region is provided with at least one light-emitting unit. When the stretchable area is not stretched, light-emitting centers of the plurality of light-emitting units are arranged in a non-uniform mode, and after the stretchable area is stretched, the light-emitting centers of the light-emitting units are arranged in a uniform mode.

### TECHNICAL FIELD

The present disclosure belongs to the field of display technology, and specifically relates to a display substrate, a display device and a mask.

### BACKGROUND

With the advancement of technology, in recent years, full-screen display has gradually come into view. Organic electroluminescent displays (OLEDs) have become mainstream products in the display field due to their characteristics of self-luminescence, high brightness, high contrast, low operation voltage, capability of being manufactured as flexible displays, and the like.

### SUMMARY

To solve at least one of the problems in the existing art, the present disclosure provides a display substrate, a display device and a mask.

In a first aspect, an embodiment of the present disclosure provides a display substrate, having a stretchable area including an opening region, a bridge region and an island region; the display substrate includes:

a base substrate;

a plurality of light-emitting units, each light-emitting unit including a light-emitting device of at least one color; each island region is provided with at least one of the light-emitting units; and

in a case where the stretchable area is not stretched, light-emitting centers of the plurality of light-emitting units are arranged in a non-uniform mode, and in a case where the stretchable area has been stretched, the light-emitting centers of the light-emitting units are arranged in a uniform mode.

In the case where the stretchable area is not stretched, an extension direction of a connection line connecting the light-emitting centers of at least some adjacent two light-emitting units in a same row forms an angle with a row direction of the light-emitting units; and in the case where the stretchable area has been stretched, an extension direction of a connection line connecting light-emitting centers of the light-emitting units in a same row is parallel to the row direction of the light-emitting units.

The light-emitting device includes a first electrode, a pixel defining layer, a light-emitting layer and a second electrode disposed on the base substrate;

the pixel defining layer includes a pixel opening from which the first electrode is exposed and in which the light-emitting layer is located, and the second electrode covers the light-emitting layer.

In a case where the stretchable area is not stretched, at least some adjacent two light-emitting devices among the light-emitting devices in a same row and emitting light of a same color have different distances between centers of the pixel openings of the at least some adjacent two light-emitting devices.

The display substrate further includes a main display area; and the light-emitting units are further disposed in the main display area.

Each corner of the display substrate is provided with the stretchable area, and an arrangement density of the light-emitting units in the stretchable area is less than an arrangement density of the light-emitting units in the main display area.

The display substrate further includes a drive layer including a plurality of pixel drive circuits disposed on the base substrate; and the pixel drive circuits are arranged in one-to-one correspondence with the light-emitting devices to provide drive signals for the light-emitting devices.

The base substrate includes a flexible base substrate.

In a second aspect, an embodiment of the present disclosure provides a display device including the display substrate as described above.

In a third aspect, an embodiment of the present disclosure provides a mask, including a body part having pattern openings with the same shape and arranged in the same mode as pixel openings in the display substrate as described above.

The mask includes a fine metal mask.

### BRIEF DESCRIPTION OF DRAWINGS

FIG. 1 is a schematic structural diagram of a display substrate;

FIG. 2 is a schematic partition view of a stretchable area:

FIG. 3 is a diagram of an exemplary pixel circuit:

FIG. 4 is a schematic diagram of a display substrate before and after stretching;

FIG. 5 is a schematic diagram of a display substrate before and after stretching in an embodiment of the present disclosure:

FIG. 6 is a sectional view of a drive transistor and a light-emitting device in an arbitrary pixel circuit of the display substrate according to an embodiment of the present disclosure;

FIG. 7 is a schematic diagram illustrating an arrangement of light-emitting units in a stretchable area and a main display area in an embodiment of the present disclosure:

FIG. 8 is a schematic structural diagram of a mask in an embodiment of the present disclosure; and

FIG. 9 is a schematic diagram of pattern openings of a mask corresponding to a stretchable area of a display substrate according to an embodiment of the present disclosure.

### DETAIL DESCRIPTION OF EMBODIMENTS

To improve understanding of the technical solution of the present disclosure for those skilled in the art, the present disclosure will now be described in detail with the help of accompanying drawings and specific embodiments.

Unless otherwise defined, technical or scientific terms used in the present disclosure are intended to have general meanings as understood by those of ordinary skill in the art. The words “first”, “second” and similar terms used in the present disclosure do not denote any order, quantity, or importance, but are used merely for distinguishing different components. Also, the use of the terms “a”, “an”, or “the” and similar referents do not denote a limitation of quantity, but rather denote the presence of at least one. The word “comprising” or “comprises” or the like means that the element or item preceding the word includes elements or items that appear after the word or equivalents thereof, but does not exclude other elements or items. The terms “connected” or “coupled” and the like are not restricted to physical or mechanical connections, but may include electrical connections, whether direct or indirect. The words “upper”, “lower”, “left”, “right”, or the like are merely used to indicate a relative positional relationship, and when an absolute position of the described object is changed, the relative positional relationship may also be changed accordingly.

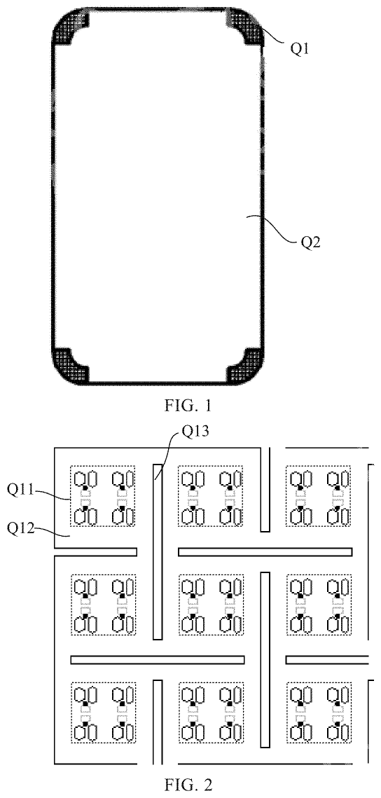

FIG. 1 is a schematic structural diagram of a display substrate which can be used in a full-screen display device. The display substrate includes a main display area Q2 and a stretchable area Q1 located at a corner of the display substrate. FIG. 1 shows a rectangular display substrate which has four stretchable areas Q1. It should be understood that, however, the display substrate in the embodiments of the present disclosure is not limited to a rectangular shape, but may have any other shape such as a circular shape, a hexagonal shape or the like. The stretchable area Q1 is not limited to be arranged at a corner of the display substrate.

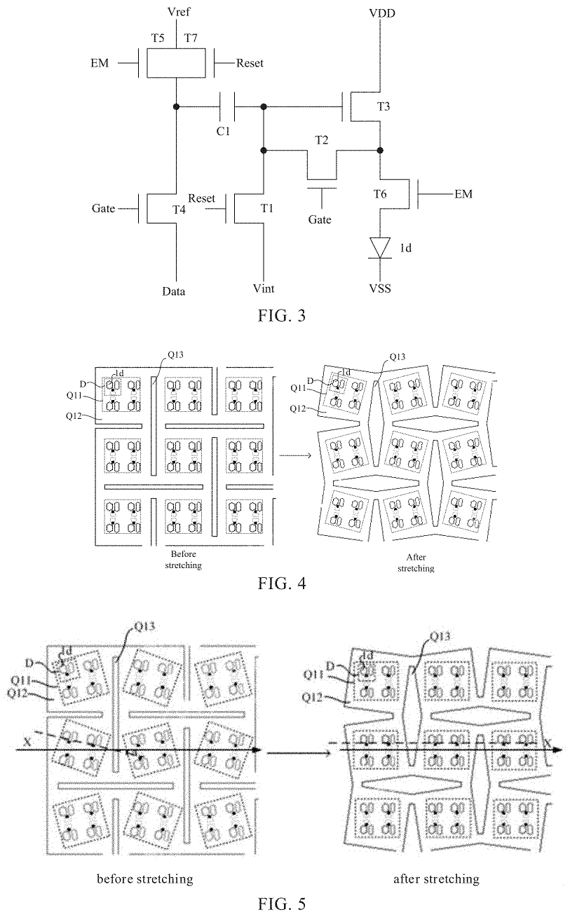

FIG. 2 illustrates a schematic partition view of a stretchable area. As shown in FIG. 2, the stretchable area Q1 includes an island region Q11, an opening region, and a bridge region Q12 between the island region Q11 and the opening region Q13. The opening region Q13 is provided to release stress when the stretchable area Q1 of the display substrate is stretched, thereby avoiding breakage of the display substrate. Each island region Q11 is provided with at least one light-emitting unit D; and each light-emitting unit D includes a light-emitting device 1d of at least one color; In FIG. 2, the case where four each island region Q11 is provided with four light-emitting units D, and each light-emitting unit D includes red, green, and blue light-emitting devices 1d is taken as an example for illustration. Each light-emitting device 1d may be an organic electroluminescent diode. Apparently, the island region Q11 is further provided with pixel drive circuits which are arranged in one-to-one correspondence with the light-emitting devices 1d and configured to provide drive signals for the light-emitting devices connected thereto. A pixel circuit is formed by each light-emitting device 1d and the pixel drive circuit connected thereto. A signal line for providing a drive signal to the pixel circuit is provided in the bridge region Q12. As shown in FIG. 3, an exemplary pixel circuit is provided. The pixel circuit specifically includes: a first reset transistor T1, a threshold compensation transistor T2, a drive transistor T3, a switch transistor T4, a first light-emitting control transistor T5, a second light-emitting control transistor T6, a second reset transistor T7, a first storage capacitor C1, and a light-emitting device 1d. A first electrode of the first transistor T1 is connected to an initial voltage signal terminal Vint, a second electrode of the first reset transistor T1 is connected to a second end of the first storage capacitor C1, a first electrode of the threshold compensation transistor T2, and a control electrode of the drive transistor T3, and a control electrode of the first reset transistor T1 is connected to a reset signal terminal Reset. A second electrode of the threshold compensation transistor T2 is connected to a second electrode of the drive transistor T3 and a first electrode of the second light-emitting control transistor T6, and a control electrode of the threshold compensation transistor T2 is connected to a gate line Gate. A first electrode of the drive transistor T3 is connected to a first supply voltage terminal VDD. A first electrode of the switch transistor T4 is connected to a data line Data, a second electrode of the switch transistor T4 is connected to a second electrode of the first light-emitting control transistor T5, a second electrode of the second reset transistor T7, and a first electrode of the first storage capacitor C1. A control electrode of the switch transistor T4 is connected to the gate line. A first electrode of the first light-emitting control transistor T5 is connected to a reference voltage signal terminal Vref, and a control electrode of the first light-emitting control transistor T5 is connected to a light-emitting control line EM. A second electrode of the second light-emitting control transistor T6 is connected to a first electrode of the light-emitting device 1d, and a control electrode of the second light-emitting control transistor T6 is connected to the light-emitting control line EM. A first electrode of the second reset transistor T7 is connected to the reference voltage signal terminal Vref, a control electrode of the second reset transistor T7 is connected to the reset signal terminal Reset, and a second electrode of the light-emitting device 1d is connected to a second supply voltage terminal VSS.

FIG. 4 is a schematic diagram of a display substrate before and after stretching. The inventor has found that the respective light-emitting units D generally have a same structure, and the light-emitting devices 1d of a same color also have a same structure, and before the display substrate is stretched, light-emitting centers of the respective light-emitting units D located in the stretchable area Q1 are arranged uniformly, as shown in FIG. 4. It should be noted here that a light-emitting center refers to a center point of a light-emitting area of each light-emitting unit D, i.e., the schematic “black dot” in each light-emitting unit in FIG. 4. However, since the opening region Q13 is provided in the stretchable area Q1, when the display substrate is stretched by a preset stretching amount, the light-emitting device 1d is rotated. Since different light-emitting devices 1d are at different distances from an application point of the stretching force, different light-emitting devices 1d are rotated by different rotation angles. Typically, a stretching amount of 5% leads to a rotation angle of about 100 of a light-emitting device 1d. In this manner, the light-emitting centers of the light-emitting units D in the stretchable area Q1 are changed after being stretched so that the light-emitting centers in the stretchable area Q1 are no longer arranged uniformly, and thus light emission of the stretchable area Q1 is not uniform, i.e., the problem of poor display at four corners of the display device occurs.

In view of the above technical problems, embodiments of the present disclosure provide the following solutions. Before describing the technical solutions in the embodiments of the present disclosure, it should be noted that the display substrate in the embodiments of the present disclosure may include only a stretchable area Q1, or may include a stretchable area Q1 and a main display area Q2; and in the embodiments of the present disclosure, the display substrate including the stretchable area Q1 and the main display area Q2 is merely used as an example for illustration.

FIG. 5 is a schematic diagram of a display substrate before and after stretching in an embodiment of the present disclosure.

In a first aspect, an embodiment of the present disclosure provides a display substrate which, as shown in FIG. 5, has a stretchable area Q1 including an island region Q1, a bridge region Q12, and an opening region Q13. The display substrate includes a base substrate and a plurality of light-emitting units D disposed on the base substrate, each light-emitting unit D including a light-emitting device 1d of at least one color. The light-emitting units D of the stretchable area Q1 is located in the island region Q11, and each island region Q11 is provided with at least one light-emitting unit D. When the display substrate is not stretched, the light-emitting centers of the light-emitting units D in the stretchable area Q1 are arranged in a non-uniform mode, and after the display substrate is stretched by a preset stretching amount, the light-emitting centers of the light-emitting units D in the stretchable area Q1 are arranged in a uniform mode. In the embodiments of the present disclosure, before the display substrate is stretched, the arrangement mode of the light-emitting devices 1d in the light-emitting units D is adjusted according to the stretching force to be applied to the display substrate, that is, the stretching amount that will occur in the stretchable area Q1, so that the light-emitting centers of the light-emitting units D in the stretchable area Q1 in a same row are arranged in a non-uniform mode, and after the display substrate is stretched, the light-emitting centers of the light-emitting units D in a same row are arranged in a uniform mode, thereby achieving uniform light emission of the stretchable area Q1 in the display substrate. Thus, according to the embodiments of the present disclosure, the display device can still uniformly display in the stretchable area Q1 even after the stretchable area Q1 is stretched.

In some embodiments, as shown in FIG. 5, for the light-emitting units D in the stretchable area Q1, when the stretchable area Q1 is not stretched (before stretching), an extending direction (indicated by the dotted line) of a connection line for connecting light-emitting centers of at least some adjacent two light-emitting units D of the light-emitting units D in a same row forms an angle ‘a’ with a row direction (X direction) of the light-emitting units, and after the stretchable area Q1 is stretched (after stretching), an extending direction (indicated by the dotted line) of a connection line for connecting light-emitting centers of the light-emitting units D in a same row is parallel to the row direction (X direction) of the light-emitting units D. For example: before stretching, the light-emitting centers of the light-emitting units D in the stretchable area Q1 are not arranged according to a certain rule, and after stretching, the light-emitting centers of the light-emitting units D in the stretchable area Q1 are arranged in an array.

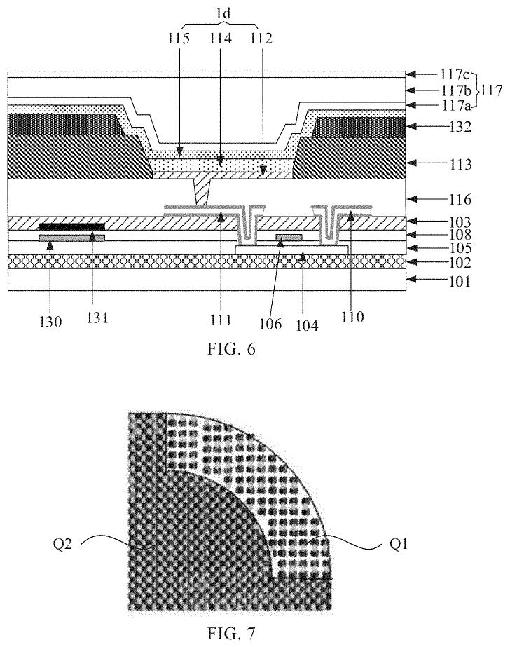

In some embodiments, the display substrate further includes, in addition to the above structures, a drive circuit layer on the base substrate, and the drive circuit layer includes pixel drive circuits in one-to-one correspondence with the light-emitting devices 1d. The pixel drive circuit may be a pixel drive circuit as shown in FIG. 3. Thin film transistors in the pixel drive circuit may be all top-gate-type thin film transistors, or all bottom-gate-type thin film transistors. It is also possible that ones of the thin film transistors are top-gate-type thin film transistors, and the other ones of the thin film transistors are bottom-gate-type thin film transistors. In the following description, only the case where the drive transistor in the pixel drive circuit is a top-gate-type thin film transistor is taken as an example for illustration. In order to clarify the relationship between the pixel drive circuit and each film layer of the light-emitting devices 1d in the embodiments of the present disclosure, illustration will be made in combination with the sectional view of a drive transistor and a light-emitting device in an arbitrary pixel circuit of the display substrate shown in FIG. 6.

As shown in FIG. 6, the base substrate may be a flexible base substrate to improve flexibility of the display substrate, so that the display substrate is flexible and bendable, or the like, so as to expand the application range of the display substrate. However, the present disclosure is not limited thereto, and the base substrate may be configured to be rigid, and the specific properties of the base substrate may be determined according to the actual requirements of the product.

In addition, the base substrate may have a single-layer structure or a multi-layer structure. The base substrate may include a polyimide layer 101 and a buffer layer 102 sequentially stacked on each other. In some other embodiments, the base substrate may include a plurality of polyimide layers 101 and buffer layers 102 sequentially stacked on one another. The buffer layer 101 may be made of a material such as silicon nitride, silicon oxide, or the like, so as to reach the effect of blocking water, oxygen and alkali ions. It should be noted that the structure of the base substrate is not limited thereto, and may be determined according to actual requirements.

It should be noted that, in order to facilitate the subsequent processing of required components in each area of the display substrate, areas, for example, a stretchable area Q1 and a main display area Q2, may be defined on the base substrate first. The stretchable area Q1 includes an island region Q11, a bridge region Q12, and an opening region.

The drive circuit layer may be formed on the base substrate. As shown in FIG. 6, the drive circuit layer may be formed on the buffer layer. The drive circuit layer may include an interlayer dielectric layer in the island region Q11, the bridge region Q12, and the main display area Q2. The interlayer dielectric layer is made of an inorganic material, for example: silicon oxide, silicon nitride, or the like, so as to reach the effect of blocking water, oxygen and alkali ions.

In detail, a portion of the drive circuit layer located in the island region Q11 may include a drive transistor and a capacitor structure.

As shown in FIG. 6, the drive transistor may be a top-gate-type thin film transistor, and the thin film transistor may include an active layer 104, a first gate insulation layer 105, a gate 106, a second gate insulation layer 108, an interlayer dielectric layer 103, a source 110, and a drain 111. Specifically, the active layer 104 may be formed on the buffer layer 102, the first gate insulation layer 105 covers the buffer layer 102 and the active layer 104, the gate 106 is formed on a side of the first gate insulation layer 105 facing away from the active layer, the second gate insulation layer 108 covers the gate and the first gate insulation layer 105, the interlayer dielectric layer 103 covers the second gate insulation layer 108, the source 110 and the drain 11l are formed on a side of the interlayer dielectric layer 103 facing away from the base substrate and respectively located on two opposite sides of the gate 106, and the source 110 and the drain 111 may respectively contact two opposite sides of the active layer 104 through via holes.

As shown in FIG. 6, the capacitor structure may include a first plate 130 and a second plate 131. The first plate 130 is disposed on the same layer as the gate 106, and the second plate 131 is disposed between the second gate insulation layer 108 and the interlayer dielectric layer 103 and opposite to the first plate 130.

For example, the gate 106, the first plate 130 and the second plate 131 may be made of a metal material or an alloy material, such as molybdenum, aluminum, titanium, and the like. The source 110 and the drain 111 may include a metal material or an alloy material, such as a metal single-layer or a multi-layer structure formed of molybdenum, aluminum, titanium, or the like. For example, the multi-layer structure is a multi-metal layer stack, such as a three metal layer stack of titanium, aluminum and titanium (Al/Ti/Al), or the like.

As shown in FIG. 6, in the stretchable area Q1, a light-emitting device 1d is located in the island region Q1, and the light-emitting device 1d may include a first electrode 112 and a pixel defining layer 113 sequentially formed on the interlayer dielectric layer 103. It should be understood that the light-emitting device 1d may further include a light-emitting layer 114 and a second electrode 115.

In detail, when the thin film transistor on the display substrate is a top-gate-type transistor, a planarization layer 116 may be formed before manufacturing the light-emitting device 1d, and the planarization layer 116 may have a single-layer structure or a multi-layer structure. The planarization layer 116 is typically made of an organic material, such as photoresist, an acrylic-based polymer, a silicon-based polymer, or the like. As shown in FIG. 6, the first electrode 112 of the light-emitting device 1d may be connected to the drain 111 of the drive transistor through a via hole penetrating through the planarization layer 116, and the first electrode 112 may be an anode made of a material including ITO (indium tin oxide), indium zinc oxide (IZO), zinc oxide (ZnO), or the like. A material of the pixel defining layer 113 includes, but is not limited to, an organic material such as photoresist, and a portion of the pixel defining layer located in the display area may have a pixel opening from which the first electrode is exposed. The light-emitting layer 114 is located in the pixel opening and formed on the first electrode 112. The light-emitting layer may include a small-molecule organic material or a polymer-molecule organic material, which may be a fluorescent light-emitting material or a phosphorescent light-emitting material that can emit red light, green light, blue light, or white light, or the like. In addition, according to different practical needs and in different examples, the light-emitting layer 114 may further include an electron injection layer, an electron transport layer, a hole injection layer, a hole transport layer or other functional layers; the second electrode 115 covers the light-emitting layer, and the second electrode 115 has a polarity opposite to the first electrode; and the second electrode may be a cathode made of a metal material such as lithium (Li), aluminum (Al), magnesium (Mg), silver (Ag), etc.

It should be noted that, as shown in FIG. 3, the first electrode 112, the light-emitting layer 114, and the second electrode 115 may form a light-emitting device 1d. In addition, it should be noted that the first electrodes 112 of respective light-emitting devices 1d are independent of each other, and the second electrodes 115 of respective light-emitting devices 1d are connected with each other to form an entire plate. That is, the entire of the second electrodes 115 is of a whole-plate structure on the display substrate, and serves as a common electrode for the plurality of light-emitting devices 1d.

In some embodiments, as shown in FIG. 6, a support portion 132 may be further provided on a side of the pixel defining layer 113 facing away from the interlayer dielectric layer 103, and the support portion 132 may function to support a protective film layer (not shown) to prevent the protective film layer from contacting the first electrode 112 or other traces to damage the first electrode 112 or other traces. It should be noted that the protective film layer is mainly provided during transfer of semi-finished products to avoid damages to the semi-finished products during the transfer. Specifically, a protective film layer may be provided for coverage in the process of transferring a substrate on which the support portion 132 has been formed to a production line for evaporation, and the protective film layer may be removed before evaporation of the light-emitting material.

For example, the support portion 132 may be made of the same material as the pixel defining layer 113, and the support portion 132 and the pixel defining layer 113 may be formed in a same patterning process, but the present disclosure is not limited thereto. The support portion 132 may be made of a different material from the pixel defining layer 113, and the support portion 132 and the pixel defining layer 113 may be formed through different patterning processes.

In the embodiments of the present disclosure, in order to enable the light-emitting centers of the light-emitting units D to be arranged in a uniform mode after the stretchable area Q1 of the display substrate is stretched under an external force, the light-emitting centers of at least some of the light-emitting units D in the stretchable area Q1 need to be adjusted. Further, since positions of the light-emitting centers are determined by light-emitting areas of the light-emitting units D, pixel openings of the light-emitting devices 1d in those light-emitting units D need to be adjusted. In the embodiments of the present disclosure, before the stretchable area Q1 is stretched, an extending direction of a connection line connecting centers of pixel openings of at least some adjacent two light-emitting devices 1d in a same row in this region forms a certain angle with a row direction. In other words, distances between centers of pixel openings of at least some adjacent two light-emitting devices 1d in this region are different. It should be noted that, in the embodiments of the present disclosure, the first electrode 112, the light-emitting layer 114, and the second electrode 115 of each light-emitting device 1d each have an orthographic projection on the base substrate that covers at least an orthographic projection of the pixel opening of the light-emitting device 1d on the base substrate. In this manner, the pixel opening in each light-emitting unit D determines the light-emitting center of the light-emitting unit D.

In some embodiments, in the opening region Q13 of the display substrate, an opening penetrating through each film layer on the base substrate is formed on the base substrate of the display substrate at a position corresponding to the opening region Q13, and the opening penetrates through each film layer on the base substrate. In some other embodiments, the opening region Q13 of the display substrate has an opening that not only penetrates through each film layer on the base substrate, but also penetrates partially or even completely through the base substrate. With such arrangement, the stress generated by the stretchable area Q1 during stretching is released as much as possible to avoid damages to the display substrate.

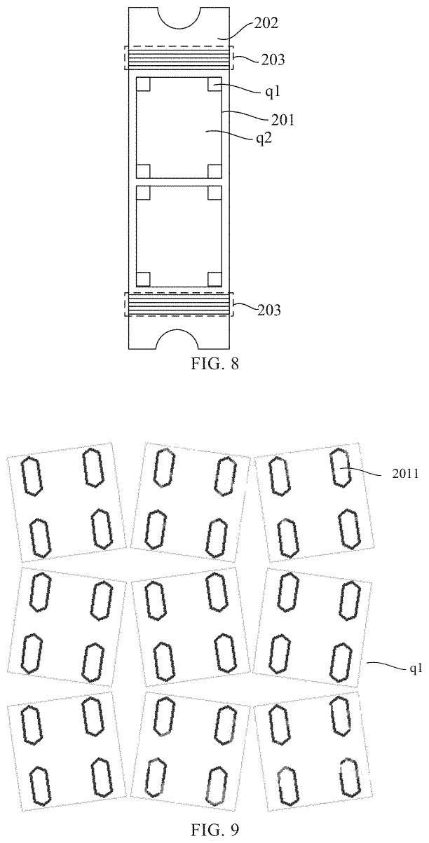

In some embodiments, FIG. 7 is a schematic diagram illustrating an arrangement of light-emitting units in a stretchable area and a main display area in an embodiment of the present disclosure. The opening region Q13 is provided in the stretchable area Q1, so, as shown in FIG. 7, the stretchable area Q1 has a resolution lower than the main display area Q2, that is, an arrangement density of the light-emitting units D in the stretchable area Q1 is smaller than that in the main display area Q2.

In some embodiments, the display substrate further includes an encapsulation layer 117, which may include a first inorganic encapsulation thin film layer 117a, an organic encapsulation thin film layer 117b, and a second inorganic encapsulation thin film layer 117c sequentially stacked on one another. The first inorganic encapsulation thin film layer 117a and the second inorganic encapsulation thin film layer 117c may be made of an inorganic material such as silicon nitride, silicon oxide, or the like. The organic encapsulation thin film layer 117b is configured to implement planarization to facilitate manufacture of the second inorganic encapsulation thin film layer 117c, and the organic encapsulation thin film layer 117b may be made of a material including an acrylic-based polymer, a silicon-based polymer, or the like.

FIG. 8 is a schematic structural diagram of a mask in an embodiment of the present disclosure; and FIG. 9 is a schematic diagram of pattern openings of a mask corresponding to a stretchable area of a display substrate according to an embodiment of the present disclosure.

In a second aspect, as shown in FIGS. 8 and 9, an embodiment of the present disclosure provides a mask, which may be a fine metal mask (FMM) for the evaporation of a light-emitting layer of a light-emitting device 1d on the display substrate according to the embodiments of the present disclosure. The mask includes a body part 201 including a first area q1 corresponding to the stretchable area Q1 of the display substrate, and a second area q2 corresponding to the main display area Q2. The body part has pattern openings 2011 in each of the first area q1 and the second area q2. Taking FIG. 9 as an example, the pattern openings 2011 of the mask correspond to pixel openings of the light-emitting devices 1d that emit light of a same color on the display substrate so that centers of the formed light-emitting units D are arranged in a uniform mode after the stretchable area Q1 of the display substrate is stretched. That is, centers of the pixel openings of the mask corresponding to the stretchable area Q1 of the display substrate in the embodiment of the present disclosure are arranged in a non-uniform mode.

The mask in the embodiment of the present disclosure further includes a fixing frame 202 configured to fix the body part 201 of the mask in a spread manner. Apparently, a stress buffer area 203 may be further provided on the mask, and located on two edges of the body part 201 closer to the fixing frame 202. By providing the stress buffer area 203, it is ensured that the pattern openings 2011 on the body part 201 will not deform after the mask is spread and stretched.

It will be appreciated that the above embodiments are merely exemplary implementations for the purpose of illustrating the principle of the disclosure, and the disclosure is not limited thereto. It will be apparent to one of ordinary skill in the art that various modifications and variations can be made to the disclosure without departing from the spirit or essence of the disclosure. Such modifications and variations should also be considered as falling into the protection scope of the disclosure.

1. A display substrate having a stretchable area, the stretchable area comprising an opening region, a bridge region and an island region; the display substrate comprising:
a base substrate; and
a plurality of light-emitting units, each first light-emitting unit comprising a light-emitting device of at least one color; each island region is provided with at least one of the light-emitting unit,
wherein in a case where the stretchable area is not stretched, light-emitting centers of the plurality of light-emitting units are arranged in a non-uniform mode, and in a case where the stretchable area has been stretched, the light-emitting centers of the light-emitting units are arranged in a uniform mode.

2. The display substrate according to claim 1, wherein in the case where the stretchable area is not stretched, an extension direction of a connection line connecting the light-emitting centers of at least some adjacent two light-emitting units in a same row forms an angle with a row direction of the light-emitting units, and in the case where the stretchable area has been stretched, an extension direction of a connection line connecting light-emitting centers of the light-emitting units in a same row is parallel to the row direction of the light-emitting units.

3. The display substrate according to claim 1, wherein the light-emitting device comprises a first electrode, a pixel defining layer, a light-emitting layer and a second electrode on the base substrate, and
the pixel defining layer comprises a pixel opening from which the first electrode is exposed and in which the light-emitting layer is located, and the second electrode covers the light-emitting layer.

4. The display substrate according to claim 3, wherein in a case where the stretchable area is not stretched, at least some adjacent two light-emitting devices among the light-emitting devices in a same row and emitting light of a same color have different distances between centers of the pixel openings of the at least some adjacent two light-emitting device.

5. The display substrate according to claim 1, further comprising a main display area, wherein the light-emitting units are further disposed in the main display area.

6. The display substrate according to claim 4, wherein each corner of the display substrate is provided with the stretchable area, and an arrangement density of the light-emitting units in the stretchable area is less than an arrangement density of the light-emitting units in the main display area.

7. The display substrate according to claim 1, wherein the display substrate further comprises a drive layer comprising a plurality of pixel drive circuits on the base substrate; and the pixel drive circuits are arranged in one-to-one correspondence with the light-emitting devices to provide drive signals for the light-emitting devices.

8. The display substrate according to claim 1, wherein the base substrate comprises a flexible base substrate.

9. A display device, comprising a display substrate according to claim 1.

10. A mask, comprising a body part, wherein the body part has pattern openings having the same shape and arranged in the same mode as pixel openings in the display substrate according to claim 1.

11. The mask according to claim 10, wherein the mask comprises a fine metal mask.

12. The display substrate according to claim 2, wherein the display substrate further comprises a drive layer comprising a plurality of pixel drive circuits on the base substrate; and the pixel drive circuits are arranged in one-to-one correspondence with the light-emitting devices to provide drive signals for the light-emitting devices.

13. The display substrate according to claim 3, wherein the display substrate further comprises a drive layer comprising a plurality of pixel drive circuits on the base substrate; and the pixel drive circuits are arranged in one-to-one correspondence with the light-emitting devices to provide drive signals for the light-emitting devices.

14. The display substrate according to claim 4, wherein the display substrate further comprises a drive layer comprising a plurality of pixel drive circuits on the base substrate; and the pixel drive circuits are arranged in one-to-one correspondence with the light-emitting devices to provide drive signals for the light-emitting devices.

15. The display substrate according to claim 5, wherein the display substrate further comprises a drive layer comprising a plurality of pixel drive circuits on the base substrate; and the pixel drive circuits are arranged in one-to-one correspondence with the light-emitting devices to provide drive signals for the light-emitting devices.

16. The display substrate according to claim 6, wherein the display substrate further comprises a drive layer comprising a plurality of pixel drive circuits on the base substrate; and the pixel drive circuits are arranged in one-to-one correspondence with the light-emitting devices to provide drive signals for the light-emitting devices.
